(19) United States
(12) Patent Application Publication
(10) Pub. No.: US 2015/0311385 A1
(43) Pub. Date: Oct. 29, 2015

(54) Luminous Source Utilizing Quantum Dot, and Its Manufacturing Method and Application

(71) Applicant: SHENZHEN CHINA STAR OPTOELECTRONICS TECHNOLOGY CO., LTD., Shenzhen , Guangdong (CN)

(72) Inventors: Yongyuan QIU, Shenzhen City, Guangdong (CN); Shengjer CHANG CHIEN, Shenzhen City, Guangdong (CN); Chih-tsung KANG, Shenzhen City, Guangdong (CN); Zanjia SU, Shenzhen City, Guangdong (CN)

(21) Appl. No.: 14/233,155

(22) PCT Filed: Dec. 9, 2013
(86) PCT No.: PCT/CN2013/088849

§ 371 Date: Jan. 15, 2014

(30) Foreign Application Priority Data
Dec. 2, 2013 (CN) 201310637526.6

(51) Int. Cl. H01L 33/06; H01L 33/00; H01L 33/48; H01L 33/54

(52) U.S. Cl. CPC H01L 33/06; H01L 33/54; H01L 33/0083; H01L 33/483

(57) ABSTRACT

The present invention relates to the liquid crystal display technique field, and in particular to the improvement of a direct type backlight structure. The present invention provides a luminous source utilizing the quantum dot, which comprises a substrate, the substrate is installed a light bar and a mixed light body surrounding the light bar; there is a quantum dot strip provided on the top of the mixed light body, the emitting light of the light bar is emitted after the quantum dot strip refracting, the light output surface of the quantum dot strip is curved surface. The present invention also provides a manufacturing method of the quantum dot strip and a new direct type backlight composed by utilizing the quantum dot strip. The present invention makes the light output surface of the quantum dot strip be curved surface through improving the structure of the quantum dot strip, making the light output surface of the quantum dot strip be curved surface. Achieving increase of the light diffusion angle of the emitted light running through the quantum dot strip, finally, increasing the light output angle of the luminous source.

### BACKGROUND OF THE INVENTION

1. Field of the Invention

The present invention relates to the liquid crystal display technique field, and in particular to the improvement of a backlight structure.

2. The Related Arts

Quantum Dot, QD, which also can be called nanocrystal, is a kind of nanoparticles composed of group II-VI or group III-V. The particle diameter of the quantum dot is generally between 1-10 nm, since electrons and holes are confined by the quantum, consecutive band structure becomes discrete level structure with molecular characteristics, it can emit fluorescence after being stimulated. Based on the quantum effect, the quantum dot has broad application prospects in the fields of solar cells, light-emitting devices, optical biomarkers and so on.

The optical characteristic of the quantum dot is closely linked to its size and shape. The studies discovered that the band gap of the quantum dot is inversely proportional to the size, namely, the size of the quantum dot is approximately small and the width of the band gap is approximately wide, the emitting light is offset to the blue light. Therefore, through controlling the size of the quantum dot, generating the quantum dot with the different emission spectrum. The luminous spectrum structure of the quantum dot as shown in FIG. 2, it is known in the figure that the half-peak width (about 50-60 nm) of the luminous spectrum of the quantum dot is narrower than the commonly used green phosphor (the half-peak width is about 80 nm) and red phosphor (the half-peak width is about 100 nm) commonly used in the current LED. When it is used in TV, it is able to match well to the color filter, CF, achieving the high penetration, simultaneously ensuring NTSC.

The current commercial quantum dot material is mainly utilized CdSe as the core, Cds as the shell. The quantum dot material will be caused to fail by the influence of high temperature and oxygen, therefore, the utilization of the current commercial quantum dot requires protecting the quantum dot material. There are mainly two approaches, one is to utilize the form of quantum dot film (QD-film), encapsulating the quantum dot material through PET; the other is to utilize the form of quantum dot rail (QT-rail), namely, encapsulating the quantum dot material into the hallow glass tube.

The requirement of the QD-film utilizing quantum dot material is much, and the chromaticity control in BLU is difficult, the possibility of mass production is low; and the quantum dot strip has higher possibility of mass production on the price and the chromaticity control. Nowadays, the common combination of the quantum dot strip and LED, and the structure of assembled luminous source 1 is shown as FIG. 2(a) and FIG. 2(b), which comprises the substrate 2, the substrate 2 is installed a light bar 4 and a mixed light body 3 surrounding the light bar 4; there is a quantum dot strip 6 provided on the top of the mixed light body 3, the emitting light of the light bar 4 is emitted after the quantum dot strip 6 refracting. It can be seen from the figure, the existing quantum dot strip 6 is in shape of square and strip, after combining the light bar 4, the light emitting angle of the luminous source 1 is still 120°. While utilizing the luminous source 1 described above in the direct type backlight, as shown in FIG. 3, the bottom to the top of the backlight comprises a back plate 10, a reflection plate 20, a diffusion plate 30 and a plurality of luminous sources 1 installed on the side that the reflection plate 20 facing to the diffusion plate 30. It can be known in the figure, the distance between the reflection plate 20 and the diffusion plate 30 is fixed, the light output angle of the luminous source 1 commonly utilized in the industry is substantially fixed (about 120°), through adjusting the distance between two adjacent luminous source 1, it makes the emitting light of the edge of the adjacent luminous source 1 exactly overlap on the receiving surface of the diffusion plate 30, at this time, the light distribution of the diffusion plate 30 is relatively flat, it makes the liquid crystal display has better quality of backlight, the acceptance by human eye is high. However, since the high cost of production of quantum dot, it is uneconomic to use large amount of quantum dot strip in backlight. In order to improve the efficiency of the quantum dot strip being utilized in direct type backlight and simultaneously ensuring the acceptable quality of backlight, the best solution is to achieve the reduction of the number of the quantum dot strip through increasing the light output angle of the luminous source.

### SUMMARY OF THE INVENTION

In order to solve the above issue, the present invention provides a illumination source utilizing quantum dot, which comprises a substrate, the substrate is installed a light bar and a mixed light body surrounding the light bar; there is a quantum dot strip provided on the top of the mixed light body, the emitting light of the light bar is emitted after the quantum dot strip refracting, the light output surface of the quantum dot strip is curved surface.

Furthermore, the minor axis section of the light output surface of the quantum dot strip is semi-elliptical or semi-circular.

Furthermore, the light output surface of the quantum dot strip has a concave inward groove.

Furthermore, the groove corresponds to the luminous center of the light bar.

Furthermore, the minor axis section of the light output surface of the quantum dot strip is paratactic double arch.

Furthermore, the minor axis section of the light output surface of the quantum dot strip is paratactic double wedge.

The present invention also provides a direct type backlight, the bottom to the top of which comprises a back plate, a reflection plate and a diffusion plate, it also comprises a plurality of luminous sources as described above, which is installed on the side that the reflection plate 20 facing to the diffusion plate.

The present invention also provides a manufacturing method of the quantum dot strip, which comprises the following steps: making a hollow glass tube, and then encapsulating the quantum dot material into the hollow glass tube; the first side face of the hollow glass tube corresponding to the light output surface of the quantum dot strip is curved surface.

Furthermore, the minor axis section of the first side face of the hollow glass tube is semi-elliptical or semi-circular.

Furthermore, the first side face of the hollow glass tube has a concave inward groove.

Furthermore, the groove corresponds to the luminous center of the light bar.

Furthermore, the minor axis section of the first side face of the hollow glass tube is paratactic double arch.

Furthermore, the minor axis section of the first side face of the hollow glass tube is paratactic double wedge.

The present invention also provides the second manufacturing method of the quantum dot strip, which comprises the following steps: adopting the method of model forming to produce a astigmatic component on the first light output surface of a quantum dot strip material, forming the target quantum dot strip; the top of the astigmatic component is the light output surface of the quantum dot strip, the top of the astigmatic component curved surface.

Therefore, the minor axis section of the top of the astigmatic component is semi-elliptical or semi-circular.

Therefore, the top of the astigmatic component has a concave inward groove.

Therefore, the groove corresponds to the luminous center of the light bar.

Therefore, the minor axis section of the top of the astigmatic component is paratactic double arch.

Therefore, the minor axis section of the top of the astigmatic component is paratactic double wedge.

Therefore, the refractivity of the quantum dot strip material is 1.3-1.4; the refractivity of the astigmatic component material is 1.45-1.55.

Therefore, the astigmatic component material is one of silicone, resin or silica.

Beneficial effects: the present invention making the light output surface of the quantum dot strip form curved surface through improving the structure of the quantum dot strip, achieving the increase of light diffusion angle of the emitting light of the light bar running through the quantum dot strip, finally increasing the light output angle of the luminous source. Applying this luminous source to the direct type backlight can greatly reduce the number of the luminous source under the circumstance of ensuring the non-reduction of the quality of the backlight, thereby effectively reducing the cost, saving the resources.

### BRIEF DESCRIPTION OF THE DRAWINGS

FIG. 1 is an existing emission spectrum of the quantum dot material.

FIG. 2(a) is a structure schematic diagram of the minor axis section of the existing luminous source; (b) is a structure schematic diagram of the top view of the luminous source.

FIG. 3 is a partial schematic diagram of the cross sectional structure of the existing direct type backlight.

FIG. 4 is a structure schematic diagram of the minor axis section of the luminous source in the present invention.

FIG. 5(a) is a production flow chart of the quantum dot strip of the embodiment 1 in the present invention; (b) is a structure schematic diagram and optical path of the other quantum dot strip of the embodiment 1 in the present invention.

FIG. 7 is a structure schematic diagram and optical path of the quantum dot strip of the embodiment 2 in the present invention.

FIG. 8 is a structure schematic diagram and optical path of the other quantum dot strip of the embodiment 2 in the present invention.

FIG. 9 is a structure schematic diagram and optical path of the quantum dot strip of the embodiment 3 in the present invention.

FIG. 10 is a structure schematic diagram and optical path of the other quantum dot strip of the embodiment 3 in the present invention.

FIG. 11 is a structure schematic diagram and optical path of the quantum dot strip of the embodiment 4 in the present invention.

FIG. 12 is a structure schematic diagram and optical path of the other quantum dot strip of the embodiment 4 in the present invention.

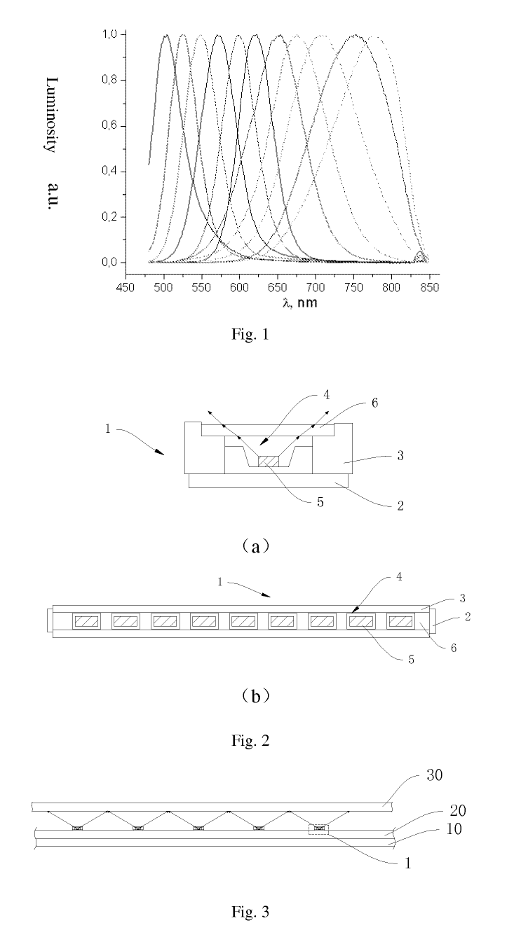

### DETAILED DESCRIPTION OF THE PREFERRED EMBODIMENTS

Hereinafter, it will be described in detail the various embodiments in the present invention with the accompanying drawings.

Embodiment 1

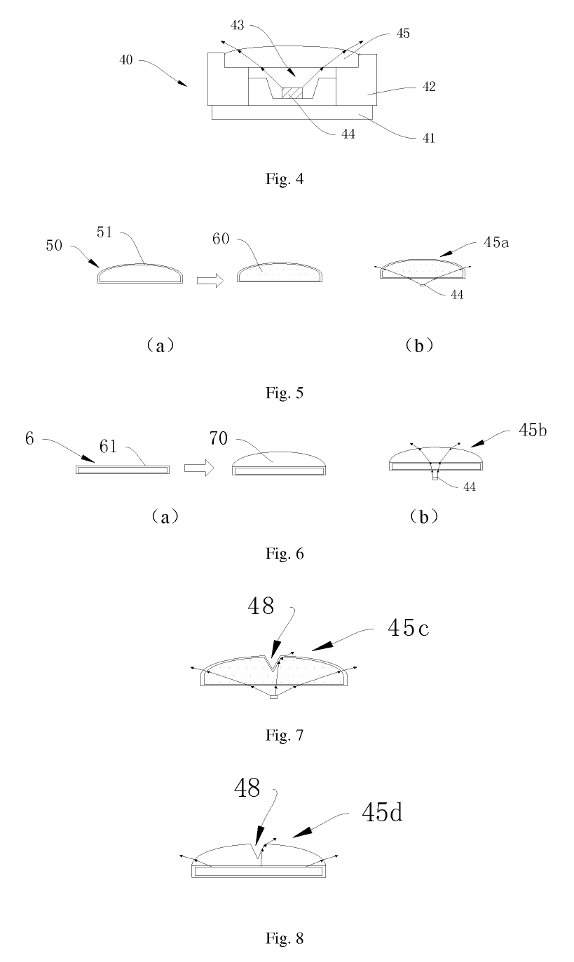

FIG. 4 illustrates the minor axis section of the luminous source 40 using the quantum dot provided in the present embodiment. The luminous source 40 comprises: a substrate 41, the substrate 41 is installed a light bar 43 and a mixed light body 42 surrounding the light bar 43. Wherein, the backlight 43 is specifically constituted by LED 44 and its circuit board. There is a quantum dot strip 45 provided on the top of the mixed light body 42, the emitting light of the light bar 43 is emitted after the quantum dot strip 45 refracting, the upper surface (light output) surface of the quantum dot strip 45 is curved surface, making the emitting light further divergent and emitted through the quantum dot strip 45, the light output angle can be 150°-160°, achieving the effective increase of the light output angle of the luminous source.

Assembling such luminous source 40 to the existing direct type backlight can obtain the significant beneficial effect. Referring to FIG. 3, replacing the luminous source 40 in the present embodiment with the existing luminous source 1, forming a new direct type backlight. The skilled person may know, under the circumstance of the distance between the reflection plate 20 and the diffusion plate 30 being relatively fixed, increasing the light output angle can increase the overlap degree of the emitting light which is on the edge of the adjacent luminous source on the receiving surface of the diffusion plate. At this time, if widening the distance between these two adjacent luminous sources, making the emitting light on the edge of the adjacent luminous source exactly overlap on the receiving surface of the diffusion plate, it still can obtain the better quality of backlight. Namely, increasing the light output angle of the luminous source on the reflection plate and diffusion plate which have the same area can reduce the installation density of the luminous source, further decreasing the used number of the quantum dot strip, reducing the cost.

Taking a direct type backlight which is 32-inch (L*W=700 mm*400 mm) for example: it requires the distance between the reflection plate 20 and the diffusion plate 30 being 25 mm, the luminous source can be arranged in an array. In order to ensure that the quality of the backlight is acceptable, according to the light output angle)(120°) of the existing luminous source 1, in the long axis direction of the reflection plate 20 needs to be installed at least 8 luminous source 1. If replacing with the luminous source 40 in the present embodiment (the light output angle increasing to 150°), on the long axis direction of the reflection plate 40 only needs to install 4 luminous sources 40 to meet the requirement.

Furthermore, in the present embodiment, it can be seen in FIG. 4, the light output surface of the quantum dot strip 45 is smoothly extensive arc, such as semi-elliptical or semi-circular. In order to achieve the purpose of the present invention, the light output surface of the quantum dot strip can have various changes of the curved surface graphic.

The present embodiment also provides a manufacturing method of the quantum dot strip, which comprises the following steps: as shown in FIG. 5(a), making a hollow glass tube 50. The first side 51 of the hollow glass tube 50 is curved surface, to be the light output surface of the quantum dot strip. And then encapsulating the quantum dot material 60 into the hollow glass tube 50 to obtain the target quantum dot strip 45a. Since the wall of the hollow glass tube 50 is relatively thin, the light refracted from the wall can be ignored, therefore, it can be known in the optical path (FIG. 5(b)) of the target production quantum dot strip 45a that the light emitted from the light output surface is further divergence, achieving the purpose of increasing the light output angle of the luminous source.

The quantum dot strip in the present embodiment also can be obtained by adopting the other manufacturing method, which specifically comprises the following steps: as shown in FIG. 6(a), adopting the modeling method to produce an astigmatism element 70 on the first light output surface 61 of the quantum dot strip raw material (it is able to adopt the existing rectangular quantum dot strip 6), forming a new quantum dot strip 45b. The top of the astigmatism element 70 is the light output surface of the quantum dot strip 45b, the top of the astigmatism element 70 is curved surface. In the manufacturing method, corresponding to the common quantum dot strip raw material (the refractivity is 1.3-1.4), the material of the astigmatism element can be adopted the rigid material which the range of the refractivity (1.45-1.55) is greater, such as silicone resin or silica and so on which are hardness, achieving the light divergence, increasing the light angle. The obtained target quantum dot strip 45b is shown as FIG. 6(b), simultaneously, the light emitted from the light output surface is further divergence, achieving the purpose of increasing the light output angle of the luminous source.

Embodiment 2

The present embodiment is further to improve or change the structure and manufacturing method of the quantum dot strip. The light output surface of the quantum dot strip in the present embodiment has a concave inward groove. For example, as shown in FIG. 7, there can be opened a groove 48 on the top of quantum dot strip 45a obtained in the embodiment 1, making the obtained light output surface is not smooth arc, forming a new quantum dot strip 45c. Furthermore, in order to make the emitting light of LED uniformly dispersed in center, the groove 48 preferably corresponds to the emitting light center of the light bar.

The quantum dot strip 45c described above can be obtained by adopting the first manufacturing method in the embodiment 1, the optical path of the obtained quantum dot strip is shown as FIG. 7, likewise, it can achieve the purpose of increasing the light output angle of the luminous source.

The present embodiment also provides the other manufacturing method of the quantum dot strip with groove, namely, it can be obtained by referring to the second manufacturing method provided in the embodiment 1. The obtained structure of the quantum dot strip 45d and its optical path are shown as FIG. 8, likewise, which can achieving the purpose of increasing the light output angle of the luminous source.

Embodiment 3

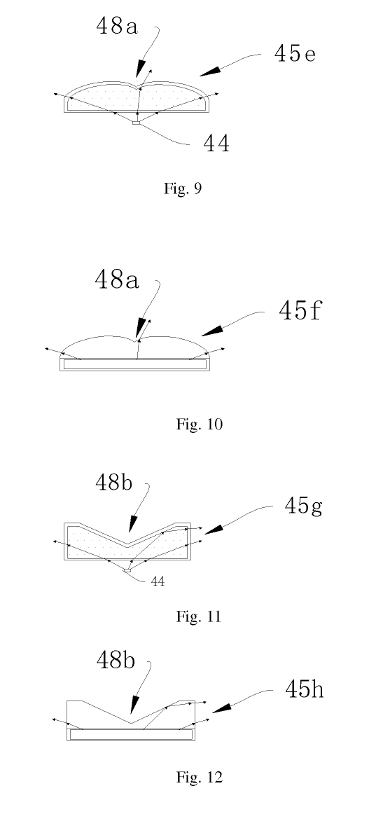

The present embodiment further improves the structure of the quantum dot strip provided is the embodiment 2, accompanying with the changes of the curved surface graphic of the light output surface of the quantum dot strip, the groove shape on the light output surface also can be changed. As shown in FIG. 9, the minor axis section of the light output surface of the quantum dot strip 45e in the present embodiment is paratactic double arch. In order to make the emitting light of LED uniformly dispersed in center, the paratactic double arch is symmetrically provided, the groove 48a composed by the double arc corresponds to the luminescence center of the light bar.

Similarly, the quantum dot strip 45e in the present embodiment can be obtained by adopting the first manufacturing method provided in the embodiment 1, the structure and the optical path are shown as FIG. 9.

It also can obtain the other quantum dot strip 45f with groove 48a through the second manufacturing method provided in the embodiment 1, the structure and the optical path are shown as FIG. 10.

Embodiment 4

The present embodiment is further to improve the structure of the quantum dot strip provided in the embodiment 2. As shown in FIG. 11, the minor axis section of the light output surface of the quantum dot strip 45g in the present embodiment is paratactic double wedge, likewise, it can achieve the purpose of the present invention. In order to make the emitted light of the LED lamp be able to diverge in maximum limitation at the bottom of groove 48b, it requires to depend on the astigmatic element or the refractivity of the quantum dot material to design the inclined slope of the bottom of the groove 48b, making the light output surface corresponding to the emitted light of the light bar at the bottom of the groove 48b form the total reflection or approximate reflection, and the reflected light emitted from the both sides of the double wedge quantum dot strip 45g, the optical path is shown as FIG. 11.

Similarly, the structure of the quantum dot strip 45g in the present embodiment can be obtained by adopting the first manufacturing method provided in the embodiment 1.

It also can obtain the other quantum dot strip 45h with groove 48b through the second manufacturing method provided in the embodiment 1, the structure and the optical path are shown as FIG. 12.

What is claimed is:

1. A luminous source utilizing quantum dot, which comprises a substrate, the substrate is installed a light bar and a mixed light body surrounding the light bar; there is a quantum dot strip provided on the top of the mixed light body, the emitting light of the light bar is emitted after the quantum dot strip refracting, wherein, the light output surface of the quantum dot strip is curved surface.

2. The luminous source as claimed in claim 1, wherein, the minor axis section of the light output surface of the quantum dot strip is semi-elliptical or semi-circular.

3. The luminous source as claimed in claim 1, wherein, the light output surface of the quantum dot strip has a concave inward groove.

4. The luminous source as claimed in claim 3, wherein, the groove corresponds to the luminous center of the light bar.

5. The luminous source as claimed in claim 4, wherein, the minor axis section of the light output surface of the quantum dot strip is paratactic double arch.

6. The luminous source as claimed in claim 4, wherein, the minor axis section of the light output surface of the quantum dot strip is paratactic double wedge.

7. A manufacturing method of the quantum dot strip as described in claim 1, which comprises the following steps: making a hollow glass tube, and then encapsulating the quantum dot material into the hollow glass tube; wherein, the first side face of the hollow glass tube corresponding to the light output surface of the quantum dot strip is curved surface.

8. The manufacturing method of the quantum dot strip as claimed in claim 7, wherein, the minor axis section of the first side face of the hollow glass tube is semi-elliptical or semi-circular.

9. The manufacturing method of the quantum dot strip as claimed in claim 7, wherein, the first side face of the hollow glass tube has a concave inward groove.

10. The manufacturing method of the quantum dot strip as claimed in claim 9, wherein, the groove corresponds to the luminous center of the light bar.

11. The manufacturing method of the quantum dot strip as claimed in claim 10, wherein, the minor axis section of the first side face of the hollow glass tube is paratactic double arch.

12. The manufacturing method of the quantum dot strip as claimed in claim 10, wherein, the minor axis section of the first side face of the hollow glass tube is paratactic double wedge.

13. A manufacturing method of the quantum dot strip as described in claim 1, wherein, it comprises the following steps: adopting the method of model forming to produce a astigmatic component on the first light output surface of a quantum dot strip material, forming the target quantum dot strip; the top of the astigmatic component is the light output surface of the quantum dot strip, the top of the astigmatic component curved surface.

14. The manufacturing method of the quantum dot strip as claimed in claim 13, wherein, the minor axis section of the top of the astigmatic component is semi-elliptical or semi-circular.

15. The manufacturing method of the quantum dot strip as claimed in claim 13, wherein, the top of the astigmatic component has a concave inward groove.

16. The manufacturing method of the quantum dot strip as claimed in claim 15, wherein, the groove corresponds to the luminous center of the light bar.

17. The manufacturing method of the quantum dot strip as claimed in claim 16, wherein, the minor axis section of the top of the astigmatic component is paratactic double arch.

18. The manufacturing method of the quantum dot strip as claimed in claim 16, wherein, the minor axis section of the top of the astigmatic component is paratactic double wedge.

19. The manufacturing method of the quantum dot strip as claimed in claim 13, wherein, the refractivity of the quantum dot strip material is 1.3-1.4; the refractivity of the astigmatic component material is 1.45-1.55.

20. The manufacturing method of the quantum dot strip as claimed in claim 19, wherein, the astigmatic component material is one of silicone, resin or silica.
